(19) United States
(12) Patent Application Publication
(10) Pub. No.: US 2026/0114187 A1
(43) Pub. Date: Apr. 23, 2026

(54) VERTICAL OFF-SET MAGNETIC TUNNEL JUNCTION CONTAINING STRUCTURE

(71) Applicant: International Business Machines Corporation, Armonk, NY (US)

(72) Inventors: Oscar van der Straten, Guilderland Center, NY (US); Koichi Motoyama, Clifton Park, NY (US); Chih-Chao Yang, Glenmont, NY (US)

(21) Appl. No.: 18/920,236

(22) Filed: Oct. 18, 2024

(51) Int. Cl. H10N 50/85; G11C 11/16; H10B 61/00; H10N 50/10

(52) U.S. Cl. CPC H10N 50/85; G11C 11/161; H10N 50/10; H10B 61/00

(57) ABSTRACT

A memory device such as a magnetoresistive random access memory is provided that includes a magnetic tunnel junction containing structure having a lower portion including a first magnetic material layer, and an upper portion including a second magnetic material layer in which the upper portion of the MTJ containing structure is off-set relative to the lower portion.

### BACKGROUND

The present application relates to semiconductor technology, and more particularly to a memory device including a magnetic tunnel junction (MTJ) containing structure having a lower portion including a first magnetic material layer, and an upper portion including a second magnetic material layer in which the upper portion is vertically off-set relative to the lower portion.

Magnetoresistive random access memory (MRAM), is a non-volatile random access memory technology in which data is stored by magnetic storage elements. These elements are typically formed from two ferromagnetic plates, each of which can hold a magnetization, separated by a thin dielectric layer (i.e., a tunnel barrier). One of the two plates is a permanent magnetic set to a particular polarity (i.e., a magnetic reference layer); the other plate's magnetization can be changed to match that of an external field to store memory (i.e., a magnetic free layer). Such a configuration is known as a magnetic tunnel junction (MTJ)-containing pillar. In leading-edge or neuromorphic computing systems, an MTJ-containing pillar is typically embedded within a back-end-of-the-line (BEOL) structure.

### SUMMARY

A memory device such as a MRAM is provided that includes a MTJ containing structure having a lower portion including a first magnetic material layer, and an upper portion including a second magnetic material layer in which the upper portion of the MTJ containing structure is vertically off-set relative to the lower portion. By “off-set” it is meant that the upper portion of the MTJ containing structure has outer edges that are mis-aligned relative to outer edges of the lower portion of the MTJ containing structure.

In one embodiment of the present application, the memory device includes a MTJ containing structure having a lower portion including a bottom electrode layer and a first magnetic material layer, and an upper portion including a second magnetic material layer and a top electrode layer, in which the upper portion of the MTJ containing structure is vertically off-set relative to the lower portion of the MTJ containing structure.

In another embodiment of the present application, the memory device includes a MTJ containing structure having a lower portion including a bottom electrode layer and a first magnetic material layer, and an upper portion including a second magnetic material layer and a top electrode layer, in which the upper portion of the MTJ containing structure extends over a portion of the lower portion of the MTJ containing structure and beyond an outer edge of the lower portion of the MTJ containing structure.

In yet another embodiment of the present application, the memory device includes a MTJ containing structure having a lower portion including a bottom electrode layer and a first magnetic material layer, and an upper portion including a tunnel barrier layer, a second magnetic material layer and a top electrode layer, in which the upper portion of the MTJ containing structure extends over the lower portion of the MTJ containing structure and beyond outer edges of the lower portion of the MTJ containing structure.

### BRIEF DESCRIPTION OF THE DRAWINGS

FIG. 1 is a cross sectional view of an exemplary structure that can be employed in the present application, the exemplary structure including a first electrically conductive structure embedded in a first interlayer dielectric (ILD) layer, and a dielectric cap located on the first ILD layer and the first electrically conductive structure.

FIG. 2 is a cross sectional view of the exemplary structure of FIG. 1 after forming a metal cap in the dielectric cap and on a physically exposed surface of the first electrically conductive structure.

FIG. 3 is a cross sectional view of the exemplary structure of FIG. 2 after forming a first material stack of a blanket layer of bottom electrode material and a blanket layer of first magnetic material.

FIG. 4 is a cross sectional view of the exemplary structure of FIG. 3 after patterning the first material stack including the blanket layer of bottom electrode material and the blanket layer of first magnetic material to provide a lower portion of a MTJ containing structure including a bottom electrode layer and a first magnetic material layer.

FIG. 5 is a cross sectional view of the exemplary structure of FIG. 4 after forming a first encapsulation liner on a sidewall of the lower portion of the MTJ containing structure.

FIG. 6 is a cross sectional view of the exemplary structure of FIG. 5 after forming a second ILD layer.

FIG. 7 is a cross sectional view of the exemplary structure of FIG. 6 after forming a tunnel barrier layer on top of the lower portion of the MTJ containing structure and the second ILD layer, the tunnel barrier layer is vertically off-set from both the bottom electrode layer and the first magnetic material layer of the lower portion of the MTJ containing structure.

FIG. 8 is a cross sectional view of the exemplary structure of FIG. 7 after forming a tunnel barrier encapsulation liner on a sidewall of the tunnel barrier layer.

FIG. 9 is a cross sectional view of the exemplary structure of FIG. 8 after forming a layer of additional ILD material adjacent to the tunnel barrier encapsulation liner.

FIG. 10 is a cross sectional view of the exemplary structure of FIG. 9 after forming a second material stack of a blanket layer of second magnetic material and a blanket layer of top electrode material.

FIG. 11 is a cross sectional view of the exemplary structure of FIG. 10 after patterning the second material stack including the blanket layer of second magnetic material and the blanket layer of top electrode material to provide an upper portion of MTJ containing structure including a second magnetic material layer and a top electrode layer, the upper portion of the MTJ containing structure is vertically off-set from both the tunnel barrier layer and the lower portion of the MTJ containing structure.

FIG. 12 is a cross sectional view of the exemplary structure of FIG. 11 after forming a second encapsulation liner on a sidewall of the upper portion of the MTJ containing structure.

FIG. 13 is a cross sectional view of the exemplary structure of FIG. 12 after forming a third ILD layer.

FIG. 14 is a cross sectional view of the exemplary structure of FIG. 12 after forming a second electrically conductive structure in the third ILD layer and in contact with a topmost surface of the upper portion of the MTJ containing structure.

FIG. 15 is a cross sectional view of the exemplary structure of FIG. 6 after forming a second material stack of a blanket layer of tunnel barrier material, a blanket layer of second magnetic material and a blanket layer of top electrode material.

FIG. 16 is a cross sectional view of the exemplary structure of FIG. 15 after patterning the second material stack including the blanket layer of tunnel barrier material, the blanket layer of second magnetic material and the blanket layer of top electrode material to provide an upper portion of the MTJ containing structure including a tunnel barrier layer, a second magnetic material layer and a top electrode layer, the upper portion of the MTJ containing structure is vertically off-set from the lower portion of the MTJ containing structure.

FIG. 17 is a cross sectional view of the exemplary structure of FIG. 16 after forming a second encapsulation liner on a sidewall of the upper portion of the MTJ containing structure.

FIG. 18 is a cross sectional view of the exemplary structure of FIG. 17 after forming a third ILD layer.

FIG. 19 is a cross sectional view of the exemplary structure of FIG. 18 after forming a second electrically conductive structure in the third ILD layer and in contact with a topmost surface of the upper portion of the MTJ containing structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

For high performance MRAM devices based on perpendicular MTJ-containing pillars, well-defined interfaces and interface control are essential. Embedded MTJ-containing pillars are usually formed by patterning a blanket MTJ-containing stack utilizing one of reactive ion etching (RIE) and ion beam etching (IBE). Processing the blanket MTJ-containing stack into a MTJ-containing pillar utilizing RIE and IBE presents a challenge as it leads to shorts caused by re-sputtered bottom electrode metal particles on the sidewall of tunnel barrier layer of the MTJ-containing pillar.

Also, and in high-performance MRAM devices, embedded MTJ-containing pillars are usually formed by subtractive etching of banket MTJ containing stacks into MTJ-containing pillars between two different metal levels. After MTJ containing stack patterning, the inter-pillar spaces are formed with an ILD material to enable connection to the back-end-of-the-line (BEOL) wiring by a top contact level. ILD gap filling between MTJ containing pillars presents another challenge since the presence of voids in the ILD material between the MTJ-containing pillars can lead to shorts.

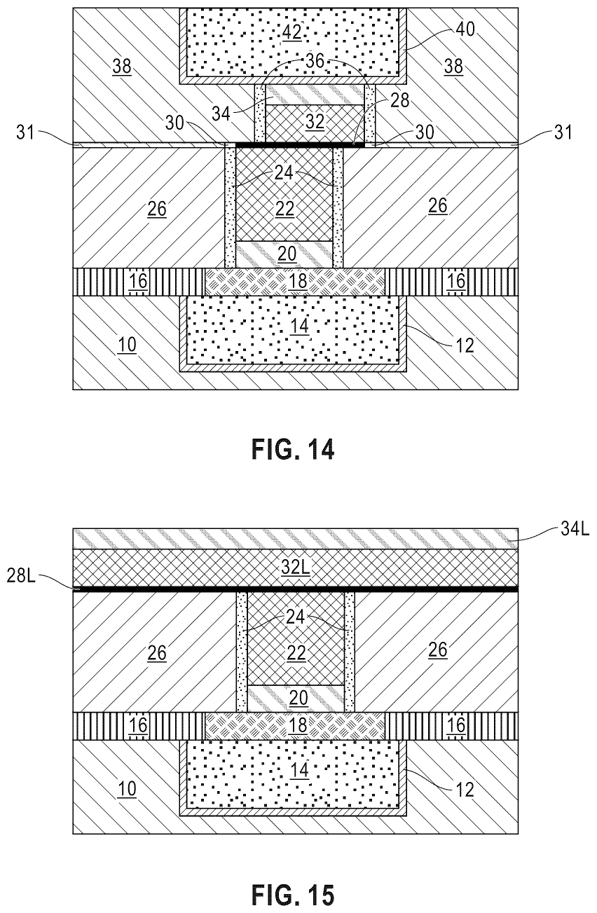

A memory device which is devoid of re-sputtered bottom electrode metal particles on the sidewall (i.e., outer edge) of tunnel barrier layer of a MTJ containing structure and is devoid of a void-containing ILD material surrounding the MTJ containing structure is provided in the present application. Notably, and as illustrated in FIGS. 14 and 19, a memory device is provided that includes a MTJ containing structure having a lower portion including bottom electrode layer 20 and first magnetic material layer 22, and an upper portion including second magnetic material layer 32 and top electrode layer 34 in which the upper portion of the MTJ containing structure is vertically off-set relative to the lower portion of the MTJ containing structure. In the present application, the term “MTJ containing structure” is used to define a structure including a bottom electrode layer, a MTJ containing portion including a tunnel barrier layer located between a first magnetic material layer and a second magnetic material layer. In the present application, the first magnetic material layer is one of a magnetic free layer or a magnetic pinned layer, and the second magnetic material layer is the other of the magnetic free layer or the magnetic pinned layer not used in the first magnetic material layer.

The MTJ containing structure (See, for example, FIGS. 14 and 19) also includes tunnel barrier layer 28 that is located between the first magnetic material layer 22 and the second magnetic material layer 32. In some embodiments and as illustrated in FIG. 14, the tunnel barrier layer 28 has a critical dimension that greater than a critical dimension of both the first magnetic material layer 22 and the second magnetic material layer 32. In the present application, the critical dimension of a layer/structure equals the lateral width of the layer/structure. In some embodiments and as is illustrated in FIG. 19, the critical dimension of the tunnel barrier layer 28 is equal to the critical dimension of the second magnetic material layer 32, and the critical dimension of both the tunnel barrier layer 28 and the second magnetic material layer 32 is greater than a critical dimension of the first magnetic material layer 22.

In some embodiments of the present application, the first magnetic material layer 22 is composed of a magnetic pinned material, while the second magnetic material layer 32 is composed of a magnetic free material. In other embodiments of the present application, the first magnetic material layer 22 is composed of a magnetic free material, while the second magnetic material layer 32 is composed of a magnetic pinned material.

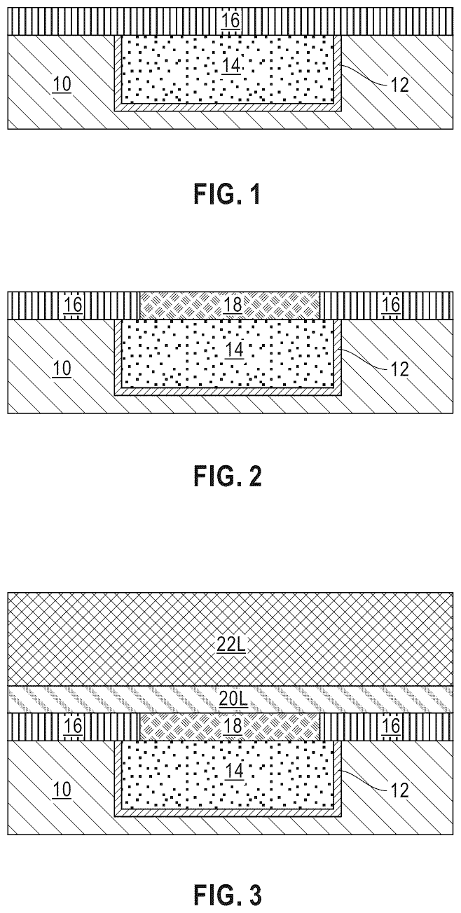

The memory device of the present application will now be described in greater detail by first referring to FIG. 1. Notably, FIG. 1 illustrates an exemplary structure that can be employed in the present application in forming the memory device. The illustrated exemplary structure includes a first electrically conductive structure 14 embedded in a first ILD layer 10, and a dielectric cap 16 located on the first ILD layer 10 and the first electrically conductive structure 14. In some embodiments and as is illustrated in FIG. 1, a first diffusion barrier liner 12 can be present along a sidewall and a bottom surface of the first electrically conductive structure 14. In other embodiments, the first diffusion barrier liner 12 can be omitted. Collectively, the first electrically conductive structure 14, if present the first diffusion barrier liner 12 and the first ILD layer 10 provide a metal (or interconnect) level, Mₙ, wherein n is any integer starting from 1; the upper limit of ‘n’ can vary and can be predetermined by the manufacturer of a specific integrated circuit. Although FIG. 1 describes and illustrates a single first electrically conductive structure 14 embedded in the first ILD layer 10, the present application contemplates embodiments when more than one first electrically conductive structure 14 is embedded in the first ILD layer 10. When more than one first electrically conductive structure 14 is embedded in the first ILD layer 10, some or all of the first electrically conductive structures can be processed to include an MTJ containing structure in which an upper portion of the MTJ containing structure is vertically off-set relative to a lower portion of the MTJ containing structure.

In some embodiments, the first electrically conductive structure 14 can extend entirely through the first ILD layer 10. In other embodiments, the first electrically conductive structure 14 extends partially through the first ILD layer 10 and in such embodiments, the first electrically conductive structure 14 can be connected to another electrically conductive structure such as, for example, a metal line and/or a metal via.

Although not illustrated in any of the drawings of the present application, a substrate can be located beneath metal level, Mₙ. The substrate can include a front-end-of-the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level that includes a plurality of lower interconnect structures embedded in a lower interconnect dielectric material layer; or any combination thereof. In one example, the substrate includes a FEOL level and a MOL level.

The metal level, Mₙ, can be formed utilizing techniques that are known to those skilled in the art. In one embodiment, a damascene process can be used in forming metal level, Mₙ. A damascene process can include forming at least one opening into the first ILD layer 10, filling the opening with an optional diffusion barrier layer, and an electrically conductive material and, if needed, performing a planarization process such as, for example, chemical mechanical planarization (CMP) to remove the diffusion barrier layer and the electrically conductive material from the topmost surface of the first ILD layer 10. The diffusion barrier layer that remains in the opening can be referred to herein as the first diffusion barrier liner 12, and the electrically conductive material that remains in the opening can be referred to herein as the first electrically conductive structure 14. In some embodiments, and as shown in FIG. 1, the first electrically conductive structure 14 has a topmost surface that is substantially coplanar with a topmost surface of the first ILD layer 10 as well as with a topmost surface of the first diffusion barrier liner 12, if the same is present. The first electrically conductive structure 14 has a first critical dimension.

The first ILD layer 10 can be composed of a dielectric material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein are measured in a vacuum unless otherwise noted. Illustrative low-k dielectric materials that can be used as the first ILD layer 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Although not shown, the first ILD layer 10 can include a multilayered structure that includes at least two different dielectric materials stacked one atop the other. The first ILD layer 10 can be formed utilizing a deposition process including, for example, chemical vapor deposition (CVD), plasma enhanced chemical vapor deposition (PECVD), evaporation or spin-on coating.

The diffusion barrier layer (and thus the first diffusion barrier liner 12) that can optionally be employed in the present application includes a diffusion barrier material (i.e., a material that serves as a barrier to prevent a conductive material such as copper from diffusing there through). Examples of diffusion barrier materials that can be used in providing the diffusion barrier layer (and thus the first diffusion barrier liner 12) include, but are not limited to, Ta, TaN, Ti, TiN, Ru, RuN, RuTa, RuTaN, W, or WN; in some instances of the present application chemical symbols, as found in the Periodic Table of Elements, are used instead of the full names of the elements or compounds. In some embodiments, the diffusion barrier material can include a material stack of diffusion barrier materials. In one example, the diffusion barrier material can be composed of a stack of Ta/TaN. The diffusion barrier layer can be formed by a deposition process such as, for example, CVD, PECVD, or physical vapor deposition (PVD).

The electrically conductive material that provides the first electrically conductive structure 14 can include an electrically conductive metal and/or an electrically conductive metal alloy. Illustrative examples of electrically conductive metals include, but are not limited to, Cu, W, Al, Co, or Ru. An illustrative example of an electrically conductive metal alloy includes Cu—Al alloy. The electrically conductive material that provides first electrically conductive structure 14 can be formed by a deposition process such as, for example, CVD, PECVD, PVD, sputtering or electroplating. In some embodiments, a reflow anneal can follow the deposition of the electrically conductive material that provides first electrically conductive structure 14. The electrically conductive structure 14 can be a metal via, a metal liner or a combined metal line/metal via.

After forming the metal level, Mₙ, dielectric cap 16 is formed. Dielectric cap 16 is composed of a dielectric capping material which is compositionally different from the dielectric material that provides the first ILD layer 10. The dielectric capping material that provides the dielectric cap 16 can include, but is not limited to, silicon nitride (SiN), or a dielectric containing atoms of silicon, nitrogen and carbon (i.e., SiNC). The dielectric cap 16 can be formed by a deposition process including, but not limited to, atomic layer deposition (ALD), CVD, PECVD or PVD.

Referring now to FIG. 2, there is illustrated the exemplary structure of FIG. 1 after forming a metal cap 18 in the dielectric cap 16 and on a physically exposed surface of the first electrically conductive structure 14. The forming of the metal cap 18 includes patterning the dielectric cap 16 to physically expose the first electrically conductive structure 14. The patterning of the dielectric cap 16 includes lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In the present application, the patterning of the dielectric cap 16 forms an opening in the dielectric cap 16 that physically exposes the first electrically conductive structure 14.

Metal cap formation continues by forming a metal that is inert as compared to the electrically conductive material present in the first electrically conductive structure 14. Illustrative examples of such inert metals include, but are not limited to, Ta, W or Ru. The forming of the metal that provides the metal cap 18 includes a deposition process, followed by planarization including CMP. The deposition process used in forming the metal that provides the metal cap 18 can include, for example, CVD, PECVD, PVD, sputtering or electroplating. The metal cap 18 that is formed has a topmost surface that is substantially coplanar with a topmost surface of the dielectric cap 16. The metal cap 18 has a second critical dimension, which is less than the first critical dimension of the first electrically conductive structure 14.

Referring now to FIG. 3, there is illustrated the exemplary structure of FIG. 2 after forming a first material stack of a blanket layer of bottom electrode material 20L and a blanket layer of first magnetic material 22L. In the present application, the first material stack including the blanket layer of bottom electrode material 20L and the blanket layer of first magnetic material 22L is formed above both the dielectric cap 16 and the metal cap 18. Notably, the blanket layer of bottom electrode material 20L is formed on the topmost surface of both the dielectric cap 16 and the metal cap 18, and the blanket layer of first magnetic material 22L is formed on the blanket layer of bottom electrode material 20L.

The blanket layer of bottom electrode material 20L is composed a conductive metal-containing material such as, for example, Ta, TaN, Ti, TiN, Ru, RuN, RuTa, RuTaN, W, WN or any combination thereof. The blanket layer of bottom electrode material 20L can be formed by a deposition process such as, for example, CVD, PECVD, ALD, sputtering or plating.

In some embodiments, the blanket layer of first magnetic material 22L includes a magnetic pinned (or reference) material. A magnetic pinned material has a fixed magnetization. The magnetic pinned material can be composed of a metal or metal alloy (or a stack thereof) that includes one or more metals exhibiting high spin polarization. In alternative embodiments, exemplary metals for the formation of the magnetic pinned material include iron, nickel, cobalt, chromium, boron, or manganese. Exemplary metal alloys can include the metals exemplified by the above. In another embodiment, the magnetic pinned material can be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that can be used include a metal such as cobalt, nickel, platinum, palladium, iridium, or ruthenium, and can be arranged as alternating layers. The strong PMA region can also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys can be arranged as alternating layers. In one embodiment, combinations of these materials and regions can also be employed as the magnetic pinned material.

In other embodiments, the blanket layer of first magnetic material 22L includes a magnetic free material. A magnetic free material has a magnetization that can be changed to match that of an external field. The magnetic free material can be composed of a magnetic material (or a stack of magnetic materials) with a magnetization that can be changed in orientation relative to the magnetization orientation of the magnetic pinned layer. It is noted that the term “magnetic free material” denotes that the magnetic material does not have a fixed magnetization as is the case with magnetic pinned materials, but instead it is free to rotate upon application of an applied voltage. Exemplary magnetic materials for the magnetic free material include alloys and/or multilayers of cobalt, iron, alloys of cobalt-iron, nickel, alloys of nickel-iron, and alloys of cobalt-iron-boron.

In some embodiments, the magnetic free material can be composed of a single magnetic free material or a multilayered stack of magnetic free materials. In some embodiments, the magnetic free material includes a non-magnetic spacer material located between a first magnetic free material and a second magnetic free material. When present, the non-magnetic metallic spacer material is composed of a non-magnetic metal or metal alloy that allows magnetic information to be transferred therethrough and also permits the two magnetic free layers to couple together magnetically, so that in equilibrium the first and second magnetic free layers are always parallel. The non-magnetic metallic spacer material allows for spin torque switching between a first magnetic free material and a second magnetic free material. The first magnetic free material and the second magnetic free material can include one of the magnetic free materials mentioned. The first magnetic free material can be compositionally the same as, or compositionally different from, the second magnetic free material.

In either embodiment mentioned above, the blanket layer of first magnetic material 22L can be formed by a deposition process such as, for example, CVD, PECVD, ALD, sputtering or plating. The non-magnetic metallic spacer material can be formed by a deposition process such as, for example, CVD, PECVD, ALD, sputtering or plating.

In some embodiments, a blanket layer of metal seed material (not shown) can be formed between the blanket layer of bottom electrode material 20L and the blanket layer of first magnetic material 22L. The blanket layer of metal seed material can be composed of Pt, Pd, Ni, Rh, Ir, Re or alloys and multilayers thereof. The blanket layer of metal seed material can be formed by a deposition process such as, for example, CVD, PECVD, ALD, sputtering or plating.

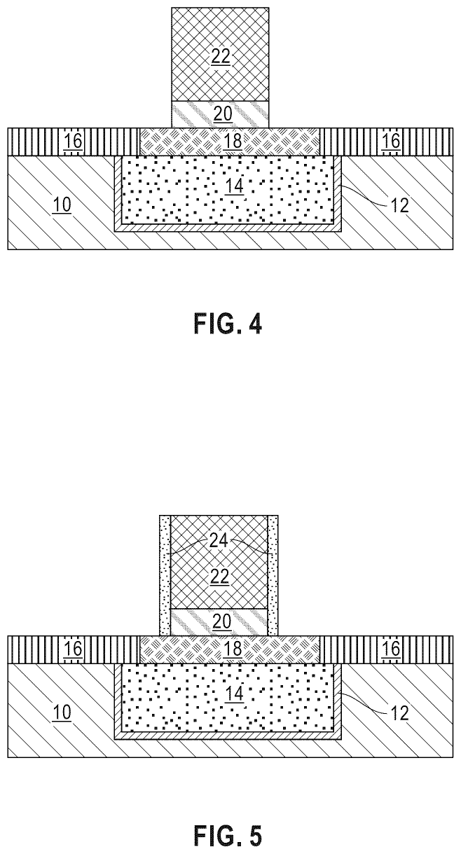

Referring now to FIG. 4, there is illustrated the exemplary structure of FIG. 3 after patterning the first material stack including the blanket layer of bottom electrode material 20L and the blanket layer of first magnetic material 22L to provide a lower portion of a MTJ containing structure including a bottom electrode layer 20 and a first magnetic material layer 22. The lower portion of the MTJ containing structure has a low aspect ratio (2:1 or less) associated therewith. In the present application, the bottom electrode layer 20 is electrically connected to the first electrically conductive structure 14 via the metal cap 18. The patterning includes a lithographic patterning process in which a patterned mask (not shown) is formed over the first material stack and then an etch such as, for example, RIE or IBE, is employed. The patterned mask protects a portion of the first material stack while leaving other portions physically exposed. The etch removes the physically exposed portions of the first material stack, while maintaining a portion of the first material stack under the patterned mask. The patterned mask is removed after pattern transfer. The bottom electrode layer 20 represents a remaining (i.e., non-etched) portion of the blanket layer of bottom electrode material 20L. The first magnetic material layer 22 represents a remaining (i.e., non-etched) portion of the blanket layer of first magnetic material 22L.

The lower portion of a MTJ containing structure has a third critical dimension. The third critical dimension is typically less than either the first critical dimension of the first electrically conductive structure 14 and the second critical dimension of the metal cap 18. The bottom electrode layer 20, the first magnetic material layer 22 and any other layer of the first material stack that is not etched have outer edges (i.e., sidewalls) that are vertically aligned with each other.

Referring now to FIG. 5, there is illustrated the exemplary structure of FIG. 4 after forming a first encapsulation liner 24 on a sidewall of the lower portion of the MTJ containing structure. The first encapsulation liner 24 is composed of an encapsulation dielectric material that can provide passivation to the lower portion of the MTJ containing structure. In some embodiments, the encapsulation dielectric material that provides the first encapsulation liner 24 can be composed of silicon nitride. In other embodiments, the encapsulation dielectric material that provides the first encapsulation liner 24 contains atoms of silicon, carbon and hydrogen. In some embodiments, and in addition to atoms of carbon and hydrogen, the encapsulation dielectric material that provides the first encapsulation liner 24 can include atoms of at least one of nitrogen and oxygen. In other embodiments, and in addition to atoms of silicon, nitrogen, carbon and hydrogen, the encapsulation dielectric material that provides the first encapsulation liner 24 can include atoms of boron. In one example, the encapsulation dielectric material that provides the first encapsulation liner 24 can be composed of an SiNC dielectric material that can contain atoms of silicon, carbon, hydrogen, nitrogen and oxygen. In alternative example, the encapsulation dielectric material that provides the first encapsulation liner 24 can be composed of a SiBCN dielectric material that contains atoms of silicon, boron, carbon, hydrogen, and nitrogen.

The first encapsulation liner 24 can be formed by depositing a conformal layer of an encapsulation dielectric material on physically exposed surfaces (i.e., sidewalls and topmost surface) of the lower portion of the MTJ containing structure and on a physically exposed surface of both the metal cap 18 and the dielectric cap 16. As used herein, the term “conformal layer” denotes that a material layer has a vertical thickness along horizontal surfaces that is substantially the same (i.e., within ±5%) as the lateral thickness along vertical surfaces. The conformal layer of encapsulation dielectric material can be formed by a conformal deposition process, including but not limited to, ALD, CVD, PECVD or PVD. The formation of the first encapsulation liner 24 continues by removing the conformal layer of encapsulation dielectric material from all horizonal surfaces of the exemplary structure, while maintaining the conformal layer of encapsulation dielectric material along the sidewall of the lower portion of MTJ containing structure. The remaining conformal layer of encapsulation dielectric material that is present along the sidewall of the lower portion of the MTJ containing structure can be referred to herein as the first encapsulation liner 24. The first encapsulation liner 24 is pillar shaped and laterally surrounds the lower portion of the MTJ containing structure. The removal of the conformal layer of encapsulation dielectric material from all horizonal surfaces can include a dielectric etch back process. As is illustrated in FIG. 5, the first encapsulation liner 24 is located on a sidewall of each of the bottom electrode layer 20 and the first magnetic material layer 22. The first encapsulation liner 24 has a bottommost surface that lands directly on the metal cap 18 and a topmost surface that is substantially coplanar with a topmost surface of the lower portion of the MTJ containing structure.

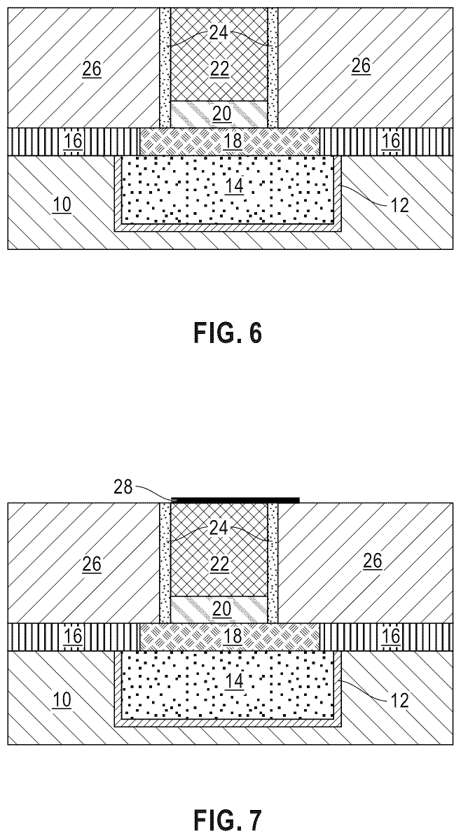

Referring now to FIG. 6, there is illustrated the exemplary structure of FIG. 5 after forming a second ILD layer 26. As is illustrated, the second ILD layer 26 is located adjacent to the first passivation liner 14 and the lower portion of the MTJ containing structure. The second ILD layer 26 is located on a physically exposed surface of both the dielectric cap 16 and the metal cap 18 and has a topmost surface that is substantially coplanar with a topmost surface of both the first passivation liner 24 and the lower portion of the MTJ containing structure. The second ILD layer 26 can include a dielectric material as mentioned above for the first ILD layer 10. The dielectric material that provides the second ILD layer 26 can be compositionally the same as, or compositionally different from, the dielectric material that provides the first ILD layer 10. The second ILD layer 26 can be formed by a deposition process such as, for example, CVD, PECVD, evaporation or spin-on coating. A planarization process such as, for example, CMP, can follow the deposition of the dielectric material that provides the second ILD layer 26. Due to the low aspect ratio of the lower portion of the MTJ containing structure, there is no gap filling concerns associated with the forming of the second ILD layer 26. As such, no voids are formed in the second ILD layer 26.

Referring now to FIG. 7, there is illustrated the exemplary structure of FIG. 6 after forming a tunnel barrier layer 28 on top of the lower portion of the MTJ containing structure and the second ILD layer 26. In this embodiment of the present application, and as is illustrated in FIG. 7, the tunnel barrier layer 28 is vertically off-set from both the bottom electrode layer 20L and the first magnetic material layer 22 of the lower portion of the MTJ containing structure. The tunnel barrier layer 28 is composed of an insulator material and is formed at such a thickness as to provide an appropriate tunneling resistance. Exemplary materials for the tunnel barrier layer 28 include magnesium oxide, aluminum oxide, and titanium oxide, or materials of higher electrical tunnel conductance, such as semiconductors or low-bandgap insulators. The tunnel barrier layer 28 is formed by first depositing a blanket layer of tunnel barrier material on the physically exposed surfaces of the second ILD layer 22, the first passivation liner 24 and the lower portion of the MTJ containing structure, and then the blanket layer of tunnel barrier material is patterned (utilizing a lithographic patterning process) to provide the tunnel barrier layer 28 illustrated in FIG. 7. The depositing of the blanket layer of tunnel barrier material includes CVD, PECVD, plasma enhanced atomic layer deposition (PEALD), or PVD. The lithographic patterning can include RIE or IBE, The tunnel barrier layer 28 is present on the lower portion of the MTJ containing structure and it extends beyond at least one outer edge of the lower portion of the MTJ containing structure as shown in FIG. 7. The tunnel barrier layer 28 is thus vertically off-set (i.e., misaligned) relative to the lower portion of the MTJ containing structure. In this embodiment of the present application, the tunnel barrier layer 28 has a fourth critical dimension, which is greater than the third critical dimension of the lower portion of the MTJ containing structure. Note that since the lower portion of the MTJ containing structure is embedded in the second ILD layer 26 and since no portion of the bottom electrode layer 20 is physically exposed, the etch used in forming the tunnel barrier layer 28 does not cause bottom electrode particles to re-sputter on the outer edges of tunnel barrier layer 28. As such, shorts are avoided in the MTJ containing structure of the present application.

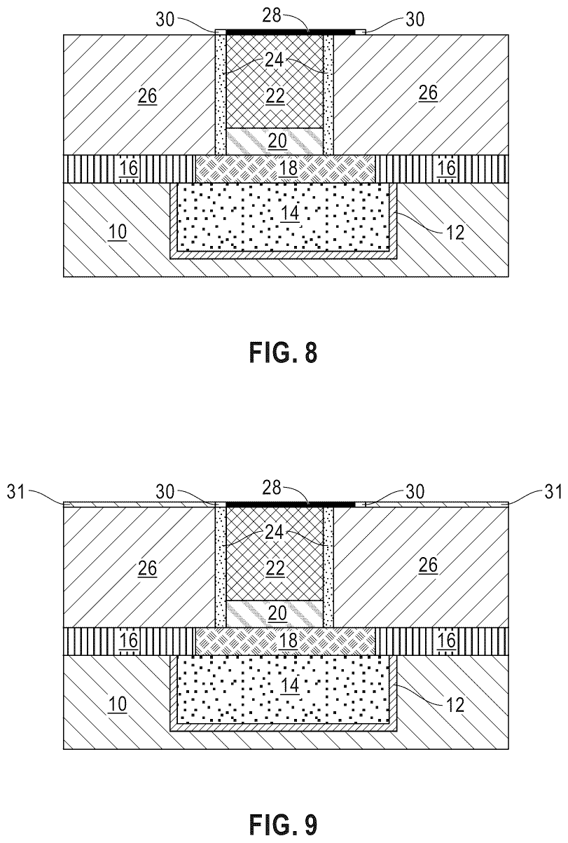

Referring now to FIG. 8, there is illustrated the exemplary structure of FIG. 7 after forming a tunnel barrier encapsulation liner 30 on a sidewall of the tunnel barrier layer 28. The tunnel barrier encapsulation liner 30 can be composed of an encapsulation dielectric material as mentioned above for the first passivation liner 24. The encapsulation dielectric material that provides the tunnel barrier encapsulation liner 30 can be compositionally the same as, or compositionally different from, the encapsulation dielectric material that provides the first passivation liner 24. The tunnel barrier encapsulation liner 30 can be formed utilizing the same technique as mentioned above in forming the first passivation liner 24. The tunnel barrier encapsulation liner 30 is pillar shaped and has a topmost surface that is substantially coplanar with a topmost surface of the tunnel barrier layer 28.

Referring now to FIG. 9, there is illustrated the exemplary structure of FIG. 8 after forming a layer of additional ILD material 31 adjacent to the tunnel barrier encapsulation liner 30. The layer of additional ILD material 31 can include a dielectric material as mentioned above for the first ILD layer 10. The dielectric material that provides the layer of additional ILD material 31 can be compositionally the same as, or compositionally different from, the dielectric material that provides the second ILD layer 26. The layer of additional ILD material 31 can be formed by a deposition process such as, for example, CVD, PECVD, evaporation or spin-on coating. A planarization process such as, for example, CMP, can follow the deposition of the dielectric material that provides the layer of additional ILD material 31. The layer of additional ILD material 31 is formed directly on the second ILD layer 26 and has a topmost surface that is substantially coplanar with a topmost surface of both the tunnel barrier layer 28 and the tunnel barrier encapsulation liner 30.

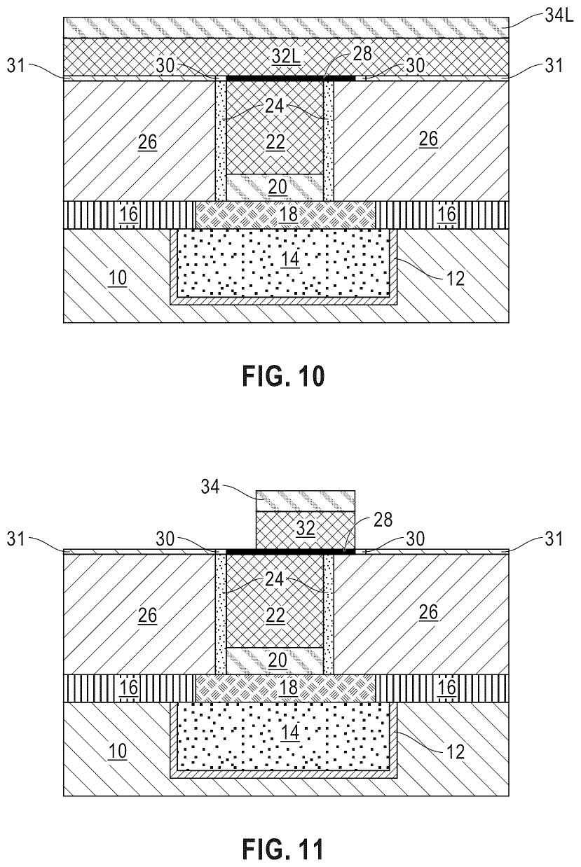

Referring now to FIG. 10, there is illustrated the exemplary structure of FIG. 9 after forming a second material stack of a blanket layer of second magnetic material 32L and a blanket layer of top electrode material 34L. In the present application, the second material stack including the blanket layer of second magnetic material 32L and the blanket layer of top electrode material 34L is formed on top each of the layer of additional ILD material 31, the tunnel barrier encapsulation liner 30 and the tunnel barrier layer 28. Notably, the blanket layer of second magnetic material 32L is formed on the topmost surface of each of the layer of additional ILD material 31, the tunnel barrier encapsulation liner 30 and the tunnel barrier layer 28, and the blanket layer of top electrode material 34L is formed on the blanket layer of second magnetic material 32L.

The blanket layer of second magnetic material 32L includes the other of the magnetic pinned material or magnetic free material not employed in the blanket layer of first magnetic 22L. In embodiments in which the blanket layer of first magnetic material 22L is composed of a magnetic pinned material (as defined above), the blanket layer of second magnetic material 32L is composed of a magnetic free material (as defined above). In embodiments in which the blanket layer of first magnetic material 22L is composed of a magnetic free material (as defined above), the blanket layer of second magnetic material 32L is composed of a magnetic pinned material (as defined above). The blanket layer of second magnetic material 32L can be formed by a deposition process such as, for example, CVD, PECVD, ALD, sputtering or plating.

The blanket layer of top electrode material 34L is composed a conductive metal-containing material such as, for example, Ta, TaN, Ti, TiN, Ru, RuN, RuTa, RuTaN, W, WN or any combination thereof. The blanket layer of top electrode material 34L can be formed by a deposition process such as, for example, CVD, PECVD, ALD, sputtering or plating.

In embodiments when the blanket layer of second magnetic material 32L is composed of a magnetic pinned material, a blanket layer of metal seed material (not shown) can be formed prior to forming the blanket layer of second magnetic material 32L. When present, the blanket layer of metal seed material can be formed by deposition process such as, for example, CVD, PECVD, ALD, sputtering or plating.

In some embodiments, a blanket layer of MTJ cap material (not shown) can be formed between the blanket layer of second magnetic material 32L and the blanket layer of top electrode material 34L. When present, the blanket layer of MTJ cap material can be composed of Nb, NbN, W, WN, Ta, TaN, Ti, TiN, Ru, Mo, Cr, V, Pd, Pt, Rh, Sc, Al or other high melting point metals or conductive metal nitrides. The blanket layer of MTJ cap material can be formed by utilizing one or more deposition processes such as, for example, CVD, PECVD, ALD, sputtering or plating.

Referring now to FIG. 11, there is illustrated the exemplary structure of FIG. 10 after patterning the second material stack including the blanket layer of second magnetic material 32L and the blanket layer of top electrode material 34L to provide an upper portion of the MTJ containing structure including a second magnetic material layer 32 and a top electrode layer 34. In this embodiment, the upper portion of the MTJ containing structure is vertically off-set from both the tunnel barrier layer 28 and the lower portion of the MTJ containing structure. The upper portion of the MTJ containing structure has a low aspect ratio (2:1 or less) associated therewith. The patterning of the second material stack includes the same technique mentioned above in patterning the first material stack. The second magnetic material layer 32 represents a remaining (i.e., non-etched) portion of the blanket layer of second magnetic material 32L. The top electrode layer 34 represents a remaining (i.e., non-etched) portion of the blanket layer of top electrode material 34L. Re-sputtering of bottom electrode particles onto the tunnel barrier layer 28 is not a concern since the bottom electrode layer 20 is not etched by this step of the present application.

In this embodiment of the present application, the upper portion of the MTJ containing structure has a fifth critical dimension. The fifth critical dimension is less than the fourth critical dimension of the tunnel barrier layer 28. The top electrode layer 34, the second magnetic material layer 32 and any other remaining layer that was initially present in the second material stack have outer edges (i.e., sidewalls) that are vertically aligned with each other.

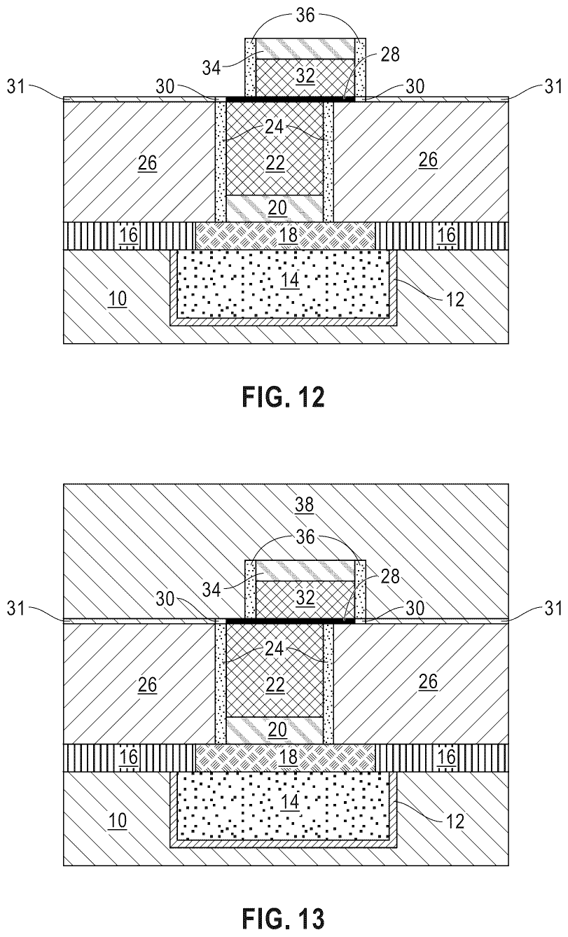

Referring now to FIG. 12, there is illustrated the exemplary structure of FIG. 11 after forming a second encapsulation liner 36 on a sidewall of the upper portion of the MTJ containing structure. The second encapsulation liner 36 is composed of an encapsulation dielectric material as mentioned above for the first passivation liner 24. The encapsulation dielectric material that provides the second encapsulation liner 36 can be compositionally the same as, or compositionally different from, the encapsulation dielectric material that provides the first passivation liner 24 and/or the tunnel barrier encapsulation liner 30. The second passivation liner 36 can be formed utilizing the same technique as mentioned above in forming the first passivation liner 24. The second encapsulation liner 36 is pillar shaped has a topmost surface that is substantially coplanar with a topmost surface of the upper portion of the MTJ containing structure.

Referring now to FIG. 13, there is illustrated the exemplary structure of FIG. 12 after forming a third ILD layer 38. The third ILD layer 38 can include a dielectric material as mentioned above for the first ILD layer 10. The dielectric material that provides the third ILD layer 38 can be compositionally the same as, or compositionally different from, the dielectric material that provides the layer of additional ILD material 31 and/or the second ILD layer 26. The third ILD layer 38 can be formed by a deposition process such as, for example, CVD, PECVD, evaporation or spin-on coating. A planarization process such as, for example, CMP, can follow the deposition of the dielectric material that provides the third ILD layer 38. In this embodiment, the third ILD layer 38 is formed directly on the layer of additional ILD material 31, the tunnel barrier layer 28 and the tunnel barrier encapsulation liner 30, and adjacent to the second passivation liner 36 that is located on the sidewall of the upper portion of the MTJ containing structure. As is illustrated, the third ILD layer 38 is formed above the topmost surface of the upper portion of the MTJ containing structure. Due to the low aspect ratio of the upper portion of the MTJ containing structure, the third ILD layer 28 is also devoid of voids.

Referring now to FIG. 14, there is illustrated the exemplary structure of FIG. 12 after forming a second electrically conductive structure 42 in the third ILD layer 38 and in contact with a topmost surface of the upper portion of the MTJ containing structure. Notably, the second electrically conductive structure 42 is in contact with the top electrode layer 34. A second diffusion barrier liner 40 can optionally be present along a sidewall and a bottom surface of the second electrically conductive structure 42. The second electrically conductive structure 42 is composed of electrically conductive material as mentioned above for the first electrically conductive structure 14. The second diffusion barrier liner 40 is composed of a diffusion barrier material as mentioned above for the first diffusion barrier liner 12. The second diffusion barrier liner 40 and the second electrically conductive structure 42 can be formed by a damascene process as mentioned above in forming the first diffusion barrier liner 12 and the first electrically conductive structure 14. In this embodiment, the second electrically conductive structure 42 is electrically connected (either directly or indirectly) to the top electrode layer 34. The second electrically conductive structure 42 has a sixth critical dimension that is typically greater than the third, fourth and fifth critical dimensions mentioned herein. The sixth critical dimension can be substantially equal to, less than or greater than, the first critical dimension of the first electrically conductive structure 14.

FIG. 14 illustrates a memory device in accordance with an embodiment of the present application. The illustrated memory device includes a MTJ containing structure having a lower portion including bottom electrode layer 20 and first magnetic material layer 22, and an upper portion including second magnetic material layer 32 and top electrode layer 34, in which the upper portion of the MTJ containing structure extends over a portion of the lower portion of the MTJ containing structure and beyond an outer edge of the lower portion of the MTJ containing structure. In embodiments, both the lower portion and the upper portion of the MTJ containing structure are embedded in an interlayer dielectric (ILD) layer that is devoid of voids.

Referring now to FIG. 15, there is illustrated the exemplary structure of FIG. 6 after forming a second material stack of a blanket layer of tunnel barrier material 28L, a blanket layer of second magnetic material 32L and a blanket layer of top electrode material 34L. The second material stack can also include other layers as mentioned above for forming the second material stack illustrated in FIG. 10. The blanket layer of tunnel barrier material 28L is composed of an insulator material as mentioned above for tunnel barrier layer 28 and is formed at such a thickness as to provide an appropriate tunneling resistance. The blanket layer of second magnetic material 32L and the blanket layer of top electrode material 34L used in this embodiment are the same as described above in forming the second material stack illustrated in FIG. 10. The blanket layer of tunnel barrier material 28L can be formed by a deposition process such as, for example, CVD, PECVD, PEALD, or PVD. Each of the blanket layer of second magnetic material 32L and the blanket layer of top electrode material 34L can be formed by a deposition process such as, for example, CVD, PECVD, ALD, sputtering or plating.

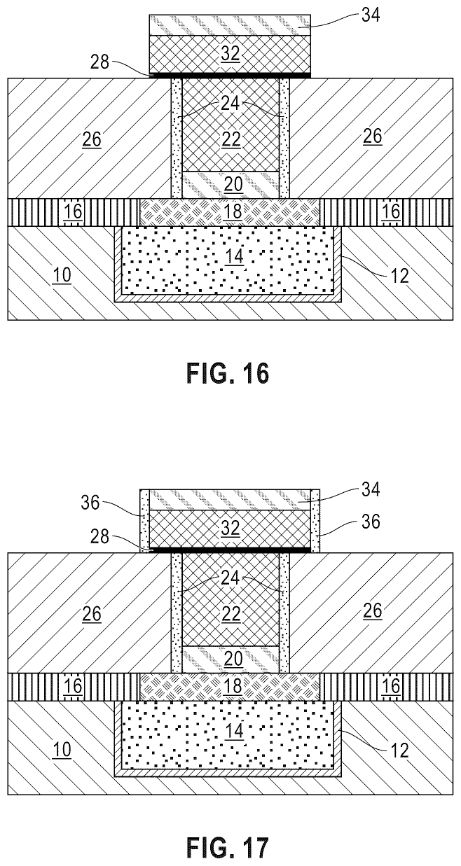

Referring now to FIG. 16, there is illustrated the exemplary structure of FIG. 15 after patterning the second material stack including the blanket layer of tunnel barrier material 28L, the blanket layer of second magnetic material 30L and the blanket layer of top electrode material.32L to provide an upper portion of the MTJ containing structure including tunnel barrier layer 28, second magnetic material layer 32 and top electrode layer 34. In this embodiment, the upper portion of the MTJ containing structure including tunnel barrier layer 28, second magnetic material layer 32 and top electrode layer 34 is vertically off-set from the lower portion of the MTJ containing structure. The upper portion of the MTJ containing structure including tunnel barrier layer 28, second magnetic material layer 32 and top electrode layer 34 has a fifth critical dimension that is less than the third critical dimension of the lower portion of the MTJ containing structure. In this embodiment, the tunnel barrier layer 28, second magnetic material layer 32 and top electrode layer 34 have outer edges that are vertically aligned to each other. In this embodiment, the upper portion of the MTJ containing structure including tunnel barrier layer 28, second magnetic material layer 32 and top electrode layer 34 extends over the lower portion of the MTJ containing structure and beyond outer edges of the lower portion of the MTJ containing structure. In this embodiment, the MTJ containing structure is a T-shaped structure in which the vertical portion of the T-shaped structure is the lower portion of the MTJ containing structure and the horizontal portion of the T-shaped structure is the upper portion of the MTJ containing structure. The patterning of the second material stack used in this embodiment is the same as described in FIG. 11. Re-sputtering of bottom electrode particles onto the tunnel barrier layer 28 is not a concern since the bottom electrode layer 20 is not etched by this step of the present application.

Referring now to FIG. 17, there is illustrated the exemplary structure of FIG. 16 after forming a second encapsulation liner 36 on a sidewall of the upper portion of the MTJ containing structure. The second encapsulation liner 36 used in this embodiment includes a dielectric material as mentioned above in describing the second encapsulation liner 36 employed in the embodiment depicted in FIG. 12. The second encapsulation liner 36 used in this embodiment can be formed utilizing the same technique as mentioned above in forming the first passivation liner 24.

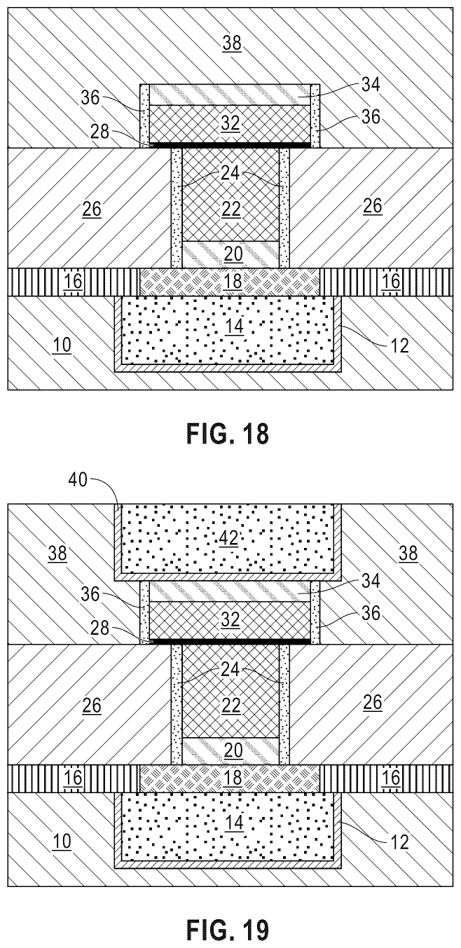

Referring now to FIG. 18, there is illustrated the exemplary structure of FIG. 17 after forming a third ILD layer 38. The third ILD layer 38 used in this embodiment includes a dielectric material as mentioned above in describing the third ILD layer 38 employed in the embodiment depicted in FIG. 13. The third ILD layer 38 used in this embodiment can be formed utilizing the technique mentioned above in forming the third ILD layer 38 illustrated in FIG. 13. In this embodiment, the third ILD layer 38 is formed directly on second ILD layer 26 and adjacent to the second passivation liner 36 that is located on the sidewall of the upper portion of the MTJ containing structure. As is illustrated, the third ILD layer 38 is formed above the topmost surface of the upper portion of the MTJ containing structure.

Referring now to FIG. 19, there is illustrated the exemplary structure of FIG. 18 after forming a second electrically conductive structure 42 in the third ILD layer 38 and in contact with a topmost surface of the upper portion of the MTJ containing structure. Notably, the second electrically conductive structure 42 is in contact with the top electrode layer 34. A second diffusion barrier liner 40 can optionally be present along a sidewall and a bottom surface of the second electrically conductive structure 42. The second electrically conductive structure 42 and the second diffusion barrier liner 40 used in this embodiment are the same as used in the embodiment illustrated in FIG. 14. Thus, the description of the second electrically conductive structure 42 and the second diffusion barrier liner 40 provided above with respect to the embodiment shown in FIG. 14 applies here for the second electrically conductive structure 42 and the second diffusion barrier liner 40 used in providing the structure illustrated in FIG. 19.

FIG. 19 illustrates a memory device in accordance with another embodiment of the present application. The memory device illustrated in FIG. 19 includes a MTJ containing structure having a lower portion including bottom electrode layer 20 and first magnetic material layer 22, and an upper portion including tunnel barrier layer 28, second magnetic material layer 32 and a top electrode layer 34, in which the upper portion of the MTJ containing structure extends over the lower portion of the MTJ containing structure and beyond outer edges of the lower portion of the MTJ containing structure. In embodiments, both the lower portion and the upper portion of the MTJ containing structure are embedded in an interlayer dielectric (ILD) layer that is devoid of voids.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory device comprising:
a magnetic tunnel junction (MTJ) containing structure having a lower portion comprising a bottom electrode layer and a first magnetic material layer and an upper portion comprising a second magnetic material layer and a top electrode layer, wherein the upper portion of the MTJ containing structure is vertically off-set relative to the lower portion of the MTJ containing structure.

2. The memory device of claim 1, further comprising a tunnel barrier layer positioned between the first magnetic material layer and the second magnetic material layer.

3. The memory device of claim 2, wherein the tunnel barrier layer has a critical dimension that is greater than a critical dimension of both the first magnetic material layer and the second magnetic material layer.

4. The memory device of claim 2, wherein the tunnel barrier layer has a critical dimension that is equal to a critical dimension of the second magnetic material layer, and the critical dimension of both the tunnel barrier layer and the second magnetic material layer is greater than a critical dimension of the first magnetic material layer.

5. The memory device of claim 1, wherein the first magnetic material layer is composed of a magnetic pinned material, and the second magnetic material layer is composed of a magnetic free material.

6. The memory device of claim 1, wherein the first magnetic material layer is composed of a magnetic free material, and the second magnetic material layer is composed of a magnetic pinned material.

7. The memory device of claim 1, further comprising a first passivation liner located on an outer edge of the lower portion of the MTJ containing structure, and a second passivation liner located on an outer edge of the upper portion of the MTJ containing structure.

8. The memory device of claim 1, wherein both the lower portion of the MTJ containing structure and the upper portion of the MTJ containing structure are embedded in an interlayer dielectric (ILD) layer that is devoid of voids.

9. The memory device of claim 1, further comprising a first electrically conductive structure located beneath and electrically connected to the lower portion of the MTJ containing by a metal cap, and a second electrically conductive structure located above and electrically connected to the upper portion of the MTJ containing structure.

10. A memory device comprising:
a magnetic tunnel junction (MTJ) containing structure having a lower portion comprising a bottom electrode layer and a first magnetic material layer and an upper portion comprising a second magnetic material layer and a top electrode layer, wherein the upper portion of the MTJ containing structure extends over a portion of the lower portion of the MTJ containing structure and beyond an outer edge of the lower portion of the MTJ containing structure.

11. The memory device of claim 10, further comprising a tunnel barrier layer positioned between the lower portion of the MTJ containing structure and the upper portion of the MTJ containing structure, wherein the tunnel barrier layer has a critical dimension that is greater than a critical dimension of both the first magnetic material layer and the second magnetic material layer.

12. The memory device of claim 10, further comprising a first passivation liner located on the outer edge of the lower portion of the MTJ containing structure, and a second passivation liner located on an outer edge of the upper portion of the MTJ containing structure.

13. The memory device of claim 10, wherein both the lower portion of the MTJ containing structure and the upper portion of the MTJ containing structure are embedded in an interlayer dielectric (ILD) layer that is devoid of voids.

14. The memory device of claim 10, further comprising a first electrically conductive structure located beneath and electrically connected to the lower portion of the MTJ containing by a metal cap, and a second electrically conductive structure located above and electrically connected to the upper portion of the MTJ containing structure.

15. A memory device comprising:
a magnetic tunnel junction (MTJ) containing structure having a lower portion comprising a bottom electrode layer and a first magnetic material layer and an upper portion comprising a tunnel barrier layer, a second magnetic material layer and a top electrode layer, wherein the upper portion of the MTJ containing structure extends over the lower portion of the MTJ containing structure and beyond outer edges of the lower portion of the MTJ containing structure.

16. The memory device of claim 15, wherein the tunnel barrier layer has a critical dimension that is equal to a critical dimension of the second magnetic material layer, and the critical dimension of both the tunnel barrier layer and the second magnetic material layer is greater than a critical dimension of the first magnetic material layer.

17. The memory device of claim 15, further comprising a first passivation liner located adjacent to the lower portion of the MTJ containing structure, and a second passivation liner located adjacent to the upper portion of the MTJ containing structure.

18. The memory device of claim 15, wherein both the lower portion of the MTJ containing structure and the upper portion of the MTJ containing structure are embedded in an interlayer dielectric (ILD) layer that is devoid of voids.

19. The memory device of claim 15, further comprising a first electrically conductive structure located beneath and electrically connected to the lower portion of the MTJ containing by a metal cap, and a second electrically conductive structure located above and electrically connected to the upper portion of the MTJ containing structure.

20. The memory device of claim 15, wherein the MTJ containing structure is a T-shaped structure, wherein the lower portion of the MTJ containing structure is a vertical portion of the T-shaped structure, and the upper portion of the MTJ containing structure is a horizontal portion of the T-shaped structure.
